(19) United States
(12) Patent Application Publication
(10) Pub. No.: US 2011/0253190 A1
(43) Pub. Date: Oct. 20, 2011

(54) SOLAR PANEL MOUNTING BRACKET AND SOLAR PANEL MOUNTING SYSTEM

(75) Inventor: Richard Robert Farnham, JR., Concord, NC (US)

(73) Assignee: Daetwyler-Clean Energy LLC, Huntersville, NC (US)

(21) Appl. No.: 13/084,922

(22) Filed: Apr. 12, 2011

Related U.S. Application Data
(60) Provisional application No. 61/324,435, filed on Apr. 15, 2010.

(51) Int. Cl. H01L 31/042; F16B 2/02; H01L 23/12

(52) U.S. Cl. 136/244; 248/214; 248/73

(57) ABSTRACT

A solar panel mounting bracket having a pipe clamp portion defining a channel between spaced legs configured to clamp around a supporting pipe, a flange clamp extending from the pipe clamp portion configured to clamp a flange of a solar panel to the bracket. A solar panel mounting system including a bracket having a pipe clamp portion defining a channel between spaced legs and a flange clamp extending from the pipe clamp portion, a solar panel having a flange on its frame, and a pipe positioned within the channel of the pipe clamp portion.

### CROSS-REFERENCE TO RELATED APPLICATION

This application claims priority to U.S. Provisional Application No. 61/324,435 filed Apr. 15, 2010 and entitled “SOLAR PANEL MOUNTING BRACKET”, the contents of which are incorporated by reference herein.

### BACKGROUND

Solar cells are commonly arranged in panels framed to protect the edges of the panels and provide structure for mounting the panels in positions to best capture sunlight. It is desirable to mount solar panels in a secure manner spaced apart from their underlying supporting surface for cooling purposes, in order to position the panels at optimum angles for capturing sunlight, and in a manner that does not interfere with the functional surface of the panels.

In this regard, the present invention is directed to solar panel mounting hardware and mounting systems for securing a framed solar panel to supporting structure, such as a tubular frame network that lends itself to customization and is lightweight.

### BRIEF SUMMARY

Accordingly, in one aspect, provided herein is a bracket for mounting a solar panel to underlying support structure, for example a tubular pipe network.

In another aspect, the bracket includes a first portion for engaging with a tubular member and a second portion for engaging with a portion of a solar panel frame.

In another aspect, the bracket captures a flange of a solar panel frame.

In another aspect, the bracket has a unitary construction including a pipe clamp portion, a flange capturing portion, and a cable routing portion.

In another aspect, a solar panel mounting system is provided herein including mounting brackets, tubular frame components and solar panel frames having an accessible flange.

To achieve the foregoing aspects and other advantages, in one embodiment a solar panel mounting bracket is provided herein including a pipe clamp portion defining a channel between spaced legs configured to clamp around a supporting pipe, and a flange clamp extending from the pipe clamp portion configured to clamp a flange of a solar panel to the bracket.

In a further embodiment, the bracket includes at least one projection extending from the pipe clamp portion in a direction away from the channel and defines a cable routing channel. In a further embodiment, the cable routing channel is cooperatively formed by and between the at least projection and the flange clamp.

In a further embodiment, the spaced legs of the pipe clamp portion define aligned openings therethrough for receiving a common fastener for urging the legs together, for example a bolt that may or may not threadably engage within at least one of the openings.

In a further embodiment, the flange clamp includes slightly spaced legs defining a thin slot therebetween, with one of the legs defining an opening therethrough for receiving a fastener for urging a captured flange of a solar panel in the direction of the other leg of the flange clamp.

In a further embodiment, a portion of the pipe clamp portion has an arcuate shape to conform to a tubular, cylindrical support member positioned in the channel.

In a further embodiment, the flange clamp is laterally offset from a longitudinal axis of the bracket defined through the channel, and the channel and slot are longitudinally spaced along the bracket.

In a further embodiment, the bracket is unitary and has a substantially consistent thickness.

In another embodiment, a solar panel mounting system is provided herein including a solar panel mounting bracket having a pipe clamp portion defining a channel between spaced legs and a flange clamp extending from the pipe clamp portion in a direction away from the channel and defining a thin slot between spaced legs, a solar panel comprising a frame having a flange positioned within the slot of the flange clamp, and a pipe positioned within the channel of the pipe clamp portion.

In a further embodiment, the bracket includes at least one projection extending from the pipe clamp in a direction away from the channel and defining a cable routing channel. In a further embodiment, the cable routing channel is cooperatively defined by the projection and the flange clamp.

### BRIEF DESCRIPTION OF THE DRAWINGS

Features, aspects and advantages of the present invention are better understood when the following detailed description of the invention is read with reference to the accompanying drawings, in which:

FIG. 1 is a perspective view of a solar panel mounting bracket in accordance with an embodiment of the invention;

FIG. 2 is another perspective view of the mounting bracket of FIG. 1;

FIG. 3 illustrates a portion of a solar panel mounting system including mounting brackets, a pipe network and framed solar panels;

FIG. 4 is a detailed view of a portion of a solar panel mounting system illustrating how a flange of a framed panel is clamped in the bracket and the bracket secured to a pipe; and

FIG. 5 illustrates a framed solar panel mounting at an angle relative to its underlying support surface.

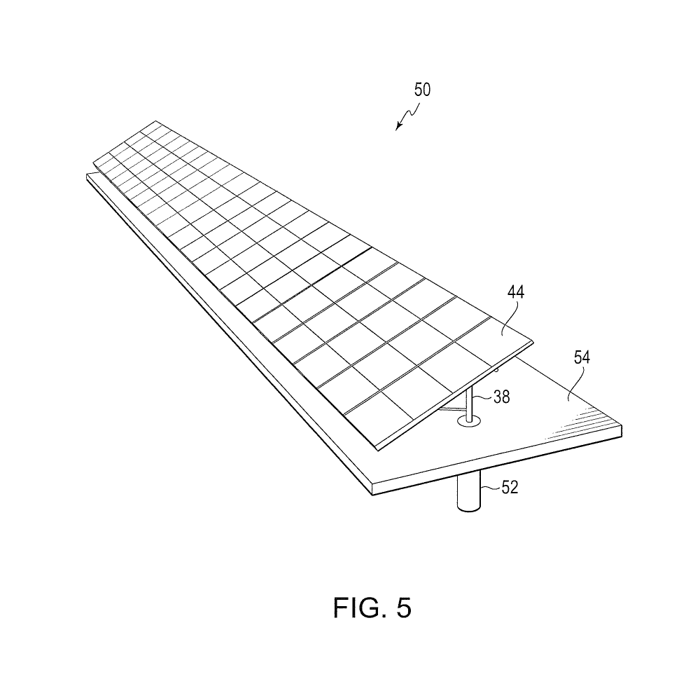

### DETAILED DESCRIPTION OF THE INVENTION

The present invention will now be described more fully hereinafter with reference to the accompanying drawings in which exemplary embodiments of the invention are shown. However, the invention may be embodied in many different forms and should not be construed as limited to the representative embodiments set forth herein. The exemplary embodiments are provided so that this disclosure will be both thorough and complete, and will fully convey the scope of the invention and enable one of ordinary skill in the art to make, use and practice the invention.

Throughout the figures, portions of the bracket are shown having a shape dictated to conform to the shape of a mating component. For example, the pipe clamp portion of the bracket illustrated in the figures has an arcuate shape for conforming to the shape of a cylindrical support member to provide tight-fit engagement. It is envisioned that portions of the bracket and other components can have alternative shapes without departing from the spirit and scope of the invention. For example, tubular support members may have a square or other sectional profile, and the bracket may have a complimentary profile to provide tight-fit engagement. In another example, the flange clamp of the bracket may be spaced differently or in a different orientation relative to the pipe clamp portion of the bracket in order to engage with specific flange structure of a solar panel.

Referring now to the figures, an exemplary embodiment of a bracket for mounting a solar panel to supporting structure is shown generally at reference numeral 10. Bracket 10 is configured to mount a solar panel, through its frame, to underlying tubular support structure, such as a component of a rooftop mounting system or other system. As shown, bracket 10 is a unitary component defining a complex shape, however, it is envisioned that the bracket may be constructed from a collection of subcomponents to achieve the same shape. Bracket 10 is preferably constructed from aluminum due to its advantageous physical properties including light weight, corrosion resistance and strength. It is envisioned that bracket 10 may be constructed from alternative materials while achieving the same desired physical properties. Bracket 10 may be provided as a stand-alone component or as a component of a larger system.

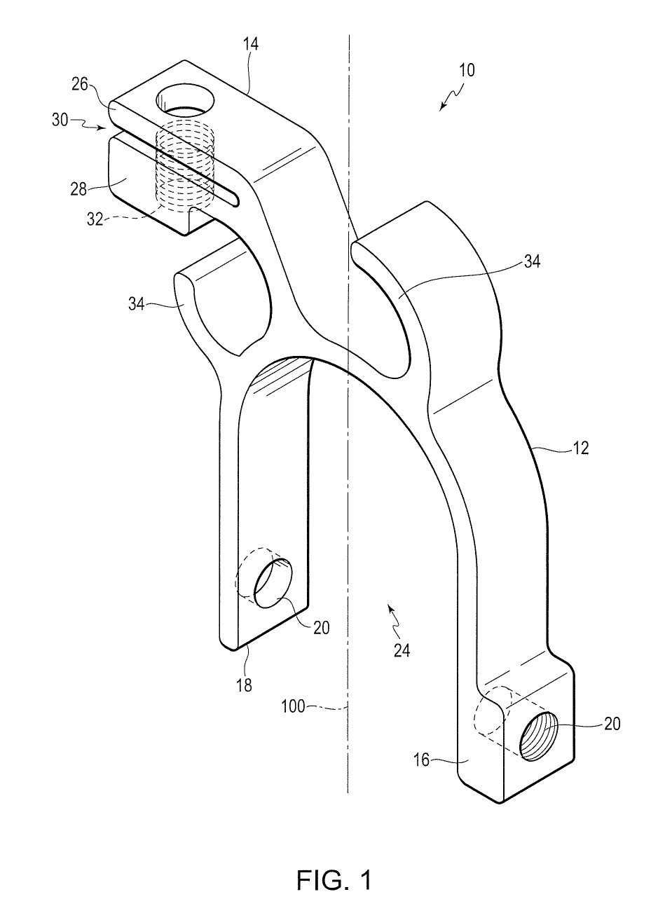

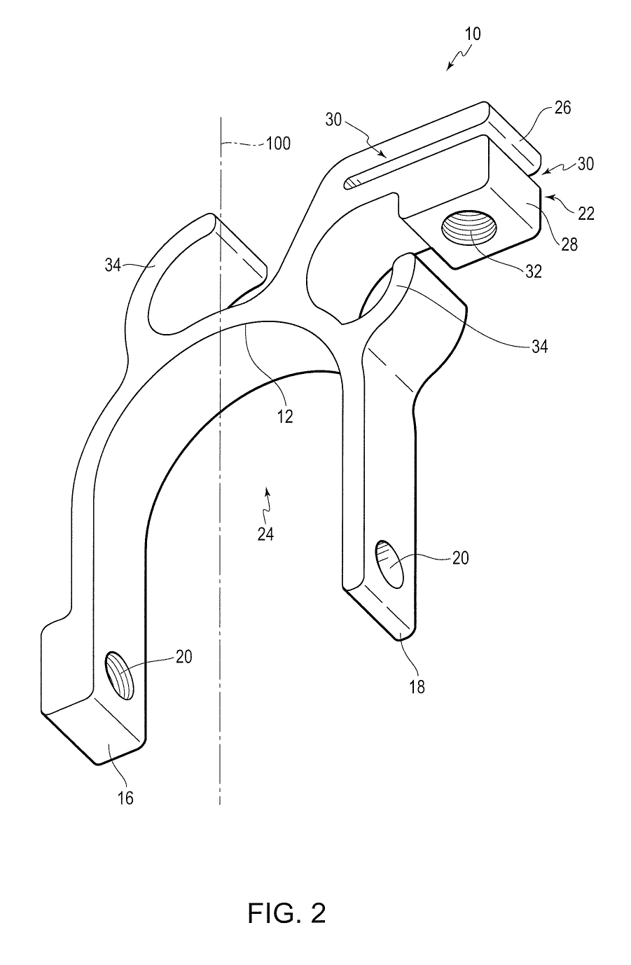

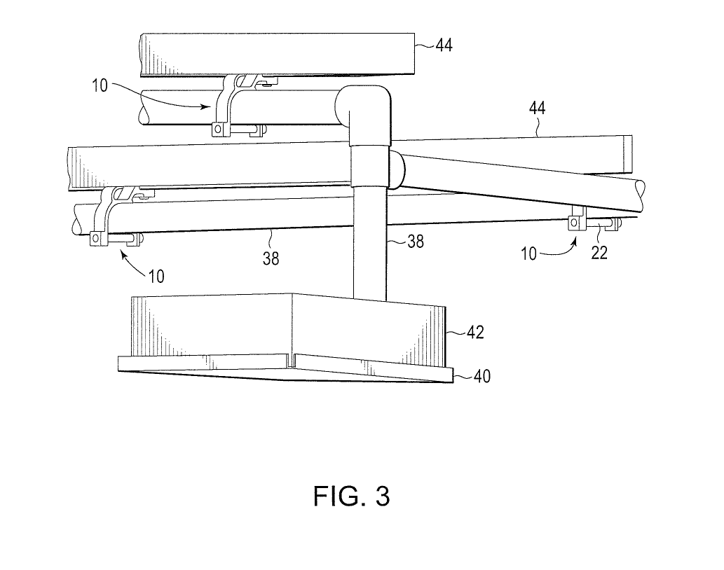

Referring specifically to FIGS. 1-2, bracket 10 generally includes a pipe clamp portion 12 and a flange clamp portion 14. Pipe clamp portion 12 includes spaced apart legs 16, 18 defining channel 24 therebetween for receiving a support structure, for example a pipe. Aligned openings 20 are defined through the ends of legs 16,18 and receive a common fastener (see FIG. 3 at 22) therethrough for urging the legs together around support structure positioned within channel 24. The free ends of legs 16, 18 extend beyond the support structure positioned within channel 24 such that the fastener 22 is free to engage openings 20. Fastener 22 can threadably engage at least one of openings 20. Pipe clamp portion 14 defines an exemplary arcuate shape to conform to a cylindrical tubular support structure.

Flange clamp 14 extends from pipe clamp portion 12 in the direction away from channel 24. Flange clamp 14 terminates in slightly spaced apart legs 26, 28 defining thin slot 30 therebetween for capturing a flange of a solar panel frame. At least one of legs 26, 28 defines an opening 32 therethrough for receiving a fastener that is advanced in opening 32 to urge the positioned flange in the direction of the other leg. For example, the fastener may be a screw threadably engaged in the opening and advanced by turning the screw from below. Slot 30 is spaced apart from pipe clamp portion 12 and laterally spaced from longitudinal axis 100 to position flange clamp 14 to the side of the pipe clamp portion.

Bracket 10 further includes at least one projection 34 extending from pipe clamp portion 12 in the direction away from channel 24 and defining a channel for routing solar panel associated cabling. As shown, bracket 10 includes two projections 34 circumferentially spaced around the arcuate portion of pipe clamp portion 12, with one positioned on each side of flange clamp 14. Flange clamp 14 and the projections 34 can cooperatively define cable routing channels.

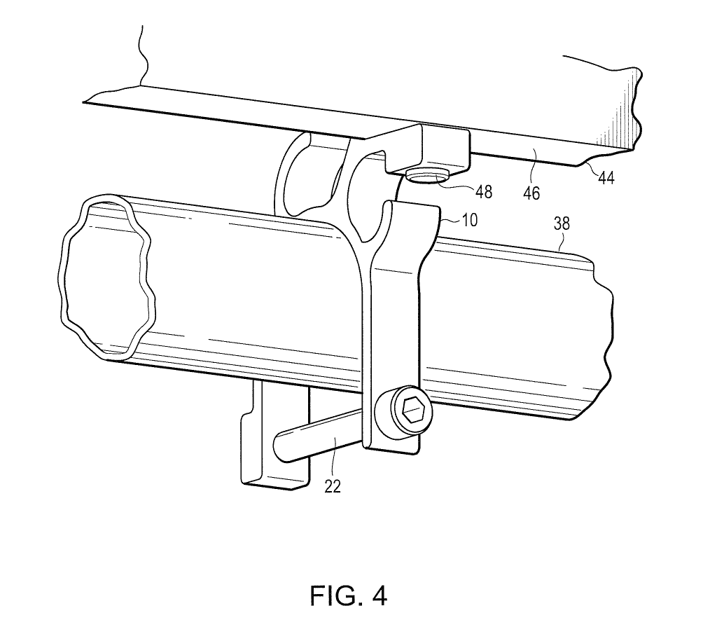

Referring to FIGS. 3-4, a solar panel mounting system generally includes at least one solar panel 44, a plurality of brackets 10, and a network of connected tubular support structure 38. The tubular network can be anchored in place by weights 42 supported on bases 40. The solar panel system may be positioned on a rooftop or elsewhere. Tubular support structure 38 preferably spaces solar panels 44 apart from the rooftop for airflow and cooling purposes. A plurality of brackets 10 are used to securely support each solar panel 44 in place on the tubular network. Each bracket 10 engages a flange on the bottom of the panel 44, for example a flange spaced from and running generally parallel to the bottom surface of the panel 44. The laterally offset construction of pipe clamp portion 12 and flange clamp 14 helps to hide bracket 10 from view from above, and is advantageously positioned to be non-obtrusive and non-interfering with the operation of solar panel 44.

The cable routing channels defined by the projections 34 maintain solar panel associated cabling in an orderly manner beneath the overlying panels. The solar panel mounting system is preferably installed without penetrating or compromising the sealing integrity of the underlying roof.

Referring specifically to FIG. 4, support pipe 38 is positioned in channel 34 and fastener 22 is advanced in the bracket to move the legs in the direction toward one another to clamp pipe 38 therebetween. Flange 46 of solar panel 44 is captured in the slot of the flange clamp and set screw 48 is advanced to tighten flange 46 against the upper leg of the flange clamp. The arrangement prevents upward pulling forces on panel 44 from pulling the panel away from the support pipe.

Referring specifically to FIG. 6, an alternative solar panel mounting system is shown generally at reference numeral 50. Solar panel 44 is arranged and secured to underlying tubular support members 38 through mounting brackets of the type shown in FIG. 1. Support members 38 are received within footings 52 in the ground 54 for support, providing a ground-mounted solar panel system.

While a mounting bracket and embodiments of solar panel mounting systems have been described with reference to specific embodiments and examples, it is envisioned that various details of the invention may be changed without departing from the scope of the invention.

What is claimed is:

1. A solar panel mounting bracket, comprising:
a pipe clamp portion defining a channel between spaced legs configured to clamp around a supporting pipe; and
a flange clamp extending from the pipe clamp portion configured to clamp a flange of a solar panel to the bracket.

2. The bracket according to claim 1, further comprising a projection extending from the pipe clamp portion defining a cable routing channel.

3. The bracket according to claim 1, wherein the spaced legs of the pipe clamp portion define aligned openings therethrough for receiving a common fastener for urging the legs together.

4. The bracket according to claim 1, wherein the flange clamp comprises slightly spaced legs defining a thin slot therebetween, one of the legs defining an opening therethrough for receiving a fastener for urging a captured flange of a solar panel in the direction of the other leg of the flange clamp.

5. A solar panel mounting bracket, comprising:
a pipe clamp portion defining a channel between spaced legs having aligned openings therethrough for receiving a common fastener for urging the spaced legs together; and
a flange clamp extending from the pipe clamp portion in a direction away from the channel and defining a thin slot between spaced legs, one of the legs of the flange clamp defining an opening therethrough for receiving a fastener for urging a captured flange of a solar panel in the direction of the other leg of the flange clamp.

6. The bracket according to claim 5, further comprising a projection extending from the pipe clamp in a direction away from the channel and defining a cable routing channel.

7. The bracket according to claim 6, wherein the cable routing channel is cooperatively defined by the projection and the flange clamp.

8. The bracket according to claim 5, wherein a portion of the pipe clamp portion has an arcuate shape to conform to a tubular support member positioned in the channel.

9. The bracket according to claim 5, wherein the flange clamp is laterally offset from a longitudinal axis of the bracket defined through the channel.

10. The bracket according to claim 5, wherein the channel and the slot are longitudinally spaced along the bracket.

11. The bracket according to claim 5, wherein the bracket is unitary.

12. A solar panel mounting system, comprising:
a solar panel mounting bracket comprising:
a pipe clamp portion defining a channel between spaced legs; and
a flange clamp extending from the pipe clamp portion in a direction away from the channel and defining a thin slot between spaced legs, one of the legs of the flange clamp defining an opening therethrough for receiving a fastener for urging a captured flange of a solar panel in the direction of the other leg of the flange clamp;
a solar panel comprising a frame having a flange positioned within the slot of the flange clamp; and
a pipe positioned within the channel of the pipe clamp portion.

13. The solar panel mounting system according to claim 12, wherein the bracket further comprises at least one projection extending from the pipe clamp in a direction away from the channel and defining a cable routing channel.

14. The solar panel mounting system according to claim 13, wherein the cable routing channel is cooperatively defined by the projection and the flange clamp.

15. The solar panel mounting system according to claim 12, wherein a portion of the pipe clamp portion has an arcuate shape to conform to the pipe positioned in the channel.

16. The solar panel mounting system according to claim 12, wherein the flange clamp is laterally offset from a longitudinal axis of the bracket defined through the channel.

17. The solar panel mounting system according to claim 12, wherein the channel and the slot are longitudinally spaced along the bracket.

18. The solar panel mounting system according to claim 12, wherein the bracket is unitary.
